(19) United States
(12) Patent Application Publication
(10) Pub. No.: US 2014/0177244 A1
(43) Pub. Date: Jun. 26, 2014

(54) LED DIE, METHOD FOR MANUFACTURING THE LED DIE AND AUTOMOBILE LAMP HAVING THE LED DIE

(71) Applicant: HON HAI PRECISION INDUSTRY CO., LTD., New Taipei (TW)

(72) Inventor: CHIH-CHEN LAI, New Taipei (TW)

(21) Appl. No.: 13/920,979

(22) Filed: Jun. 18, 2013

(30) Foreign Application Priority Data
Dec. 24, 2012 (TW) 101149432

(51) Int. Cl. H01L 33/58; F21S 8/10

(52) U.S. Cl. CPC H01L 33/58; F21S 48/00
USPC 362/487; 257/98; 438/29

(57) ABSTRACT

A light emitting diode (LED) die for use in an automobile lamp includes a light outputting surface; a concave surface is formed in a center of the light outputting surface. The concave surface is an aspheric and arc-shaped surface, with an arc-shaped edge connecting with a flat part of the light outputting surface which surrounds the concave surface. An LED automobile lamp with the LED die and a method for manufacturing the LED die are also provided.

### BACKGROUND

1. Technical Field

The present disclosure generally relates to semiconductor structure, and particularly to an LED (light emitting diode) die, a method for manufacturing the LED die and an automobile lamp having the LED die.

2. Description of the Related Art

LEDs have many advantages, such as high luminosity, low operational voltage, low power consumption, compatibility with integrated circuits, faster switching, long term reliability, and environmental friendliness which have promoted their wide use as a light source.

A typical automobile lamp structure includes an LED light source, a reflecting shell, a shading portion and a lens. The LED light source generally generates light with different brightness in a radiation angle, which leads to that the LED light source and the lens can not be directly used together to obtain a light field with a desired distribution. Accordingly, light emitted from the LED light source should be reflected by the reflecting shell and converged to the shading portion firstly. The light is then spread onto the lens from the shading portion to be regulated to a preset distribution by the lens. Then from the lens the light leaves the automobile lamp structure to illuminate the ambient environment under a low beam mode. However, the reflecting shell enlarges a volume of the automobile lamp structure and increases a manufacturing cost of the automobile lamp structure.

Therefore, it is desirable to provide an LED automobile lamp which can overcome the above-described problems.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present automobile lamp structure. Moreover, in the drawings, all the views are schematic, and like reference numerals designate corresponding parts throughout the views.

FIG. 1 is a schematic view of an LED automobile lamp in accordance with an exemplary embodiment of the present disclosure.

FIG. 2 is a cross-sectional view of an LED die of the LED automobile lamp of FIG. 1.

FIG. 3 is a schematic view of a light mask for etching the light outputting surface of the LED die of the LED automobile lamp of FIG. 1 by laser processing.

FIG. 4 shows steps of forming the LED die of the LED automobile lamp of FIG. 1.

### DETAILED DESCRIPTION

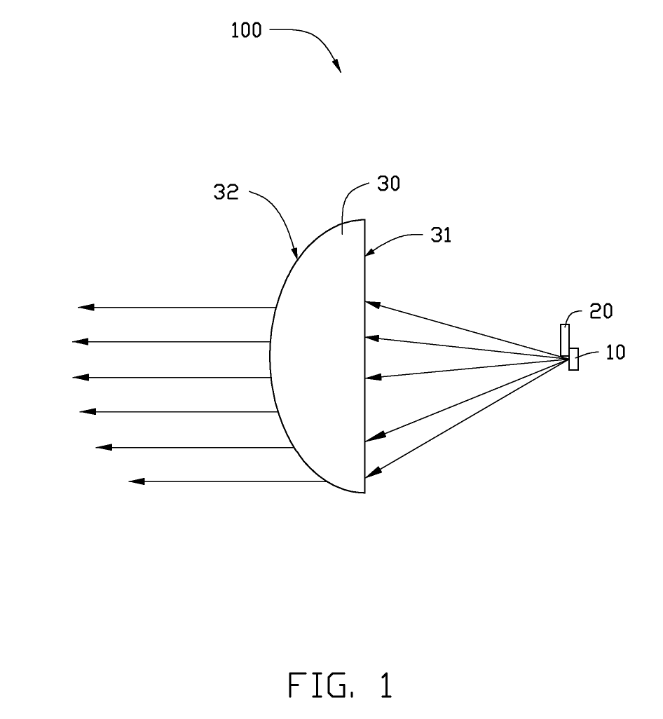

Referring to FIG. 1, an LED automobile lamp 100 in accordance with an embodiment is provided. The LED automobile lamp 100 includes a light source 10, a shading portion 20 and a lens 30. The LED automobile lamp 100 particularly is an LED automobile headlamp.

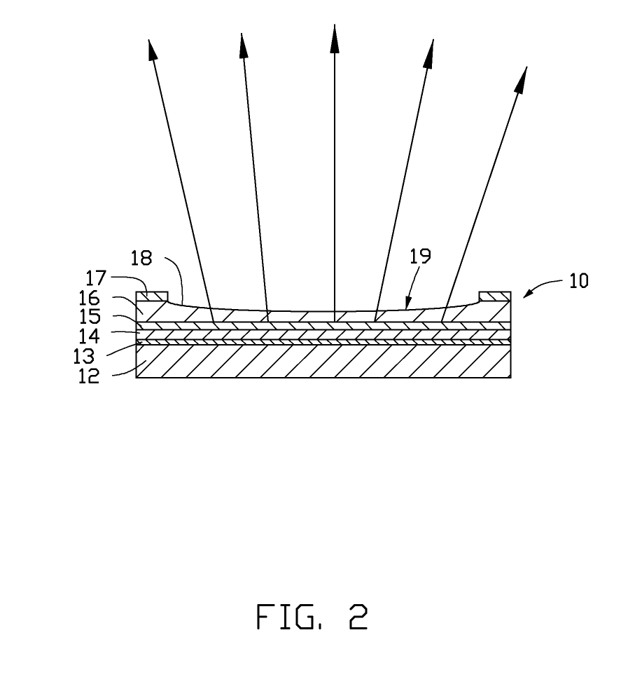

Specifically, referring to FIG. 2, the light source 10 is an LED die which includes a conductive substrate 12, a reflective layer 13 disposed on the substrate 12, a P-type semiconductor layer 14, an active layer 15, an N-type semiconductor layer 16 and two pads 17 arranged sequentially along a bottom-to-top direction on the reflective layer 13 of the light source 10.

The conductive substrate 12 is made of metal or semiconductor, wherein the metal can be such as Al, Ag, Ni, W, Cu, Pd, Cr, Au and so on. A top surface of the reflective layer 13 is flat for strengthening an output efficiency of the light source 10. In this embodiment, the P-type semiconductor layer 14 is a P-type GaN layer, the active layer 15 is a multiple quantum well (MQW) GaN/InGaN layer, and the N-type semiconductor layer 16 is an N-type GaN layer. A top surface of the N-type semiconductor layer 16 is exposed to form a light outputting surface 18. A center of the light outputting surface 18 is etched by laser to form a concave surface 19. In this embodiment, the concave surface 19 is an aspheric and arc-shaped surface, with an arc-shaped edge connecting with a flat part of the light outputting surface 18 which is located at a periphery of the light outputting surface 18. The pads 17 are located at a periphery of the light outputting surface 18 and located at above of the concave surface 19. The two pads 17 are spaced from each other. Lights generated by the light source 10 radiate out via the concave surface 19. The concave surface 19 converges the lights from the active layer 15, and the lights are concentrated toward a center of the light outputting surface 18, from which the lights radiate out of the light source 10.

The shading portion 20 is disposed between the light source 10 and the lens 30. A shape of the shading portion 20 is designed according to a luminance shape generated by the LED automobile lamp 100. Specifically, the shading portion 20 includes a bottom side surface, wherein a shape of the bottom side surface is the same as a cut-off line which complies with relevant law and regulations for low beam requirement. At a low position as shown in FIG. 1, the shading portion 20 causes the lights from the LED automobile lamp 100 to have a low beam. At a high position, the shading portion 20 does not block any lights from the light source 10 whereby the lights from the LED automobile lamp 100 have a high beam. For the low beam, when the lights from the light source 10 reach the shading portion 20, a part of the lights is blocked by the shading portion 20, and the other part passing through the shading portion 20 is regulated by the bottom side surface of the shading portion 20 to have a preset luminance shape. That is the shading portion 20 provides a cut-off line to regulate the lights generated by the light source 10 to have the preset luminance shape. Thereafter, the lights having the preset luminance shape radiate through the lens 30 to illuminate the ambient environment in a low beam mode.

The lens 30 is a convex lens. The lens 30 includes a planar first surface 31 and a convex second surface 32 protruding from a periphery of the first surface 31 along a direction away from the light source 10. The light outputting surface 18 of the light source 10 directly faces to the first surface 31. The lens 30 is spaced from the shading portion 20 and the light source 10. The second surface 32 is a spherical surface. Alternatively, the second surface 32 can be an aspheric surface.

The conductive substrate 12 and the pads 17 are arranged at different sides of the active layer 15. When the LED automobile lamp 100 works, a forward voltage is applied to two ends of the conductive substrate 12 and the pads 17, whereby electrons flow from the N-type semiconductor layer 16 to the active layer 15 to recombine with electric holes from the P-type semiconductor layer 14 to the active layer 15 by driving of an electric field. Photons are emitted to form lights from the active layer 15 where the recombination of the electrons and the electric holes occurs. The lights radiate via the concave surface 19 and are concentrated toward a center portion of the light outputting surface 18.

Since the concave surface 19 is formed at a center of the light outputting surface 18 of the light source 10. Lights generated form the light source 10 radiate from the concave surface 19 and are concentrated toward a center portion of the light outputting surface 18. Lights generated by the light source 10 can be directly transmitted to the shading portion 20 and regulated to a preset luminance shape with the cut-off line and radiate to the ambient environment via the lens 30 to illuminate the ambient environment in a low beam mode. Accordingly, the LED automobile lamp 100 can eliminate the reflector required for the conventional LED automobile lamp, whereby the LED automobile lamp 100 can have a smaller volume and the manufacturing cost of the automobile lamp 100 can be decreased.

The disclosure provides a method for manufacturing the light source 10 of the automobile lamp 100 which includes following steps:

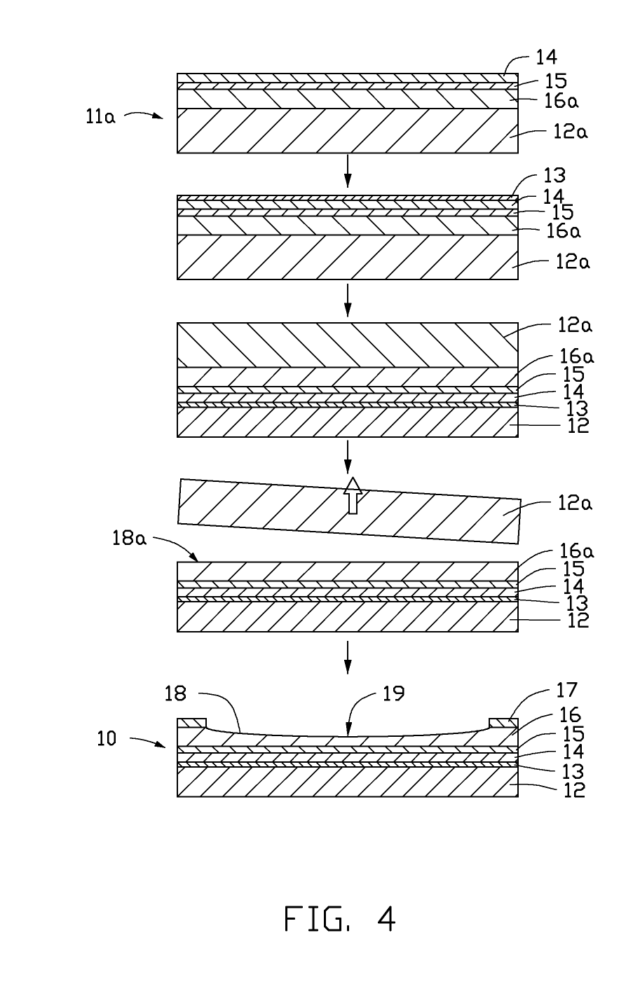

Referring to FIG. 4, from top to bottom, first a temporary substrate 12a is provided, an N-type semiconductor layer 16a is disposed on the temporary substrate 12a, an active layer 15 is disposed on the N-type semiconductor layer 16a, and a P-type semiconductor layer 14 is disposed on the active layer 15. Then, a reflective layer 13 is disposed on the P-type semiconductor layer 14.

The temporary substrate 12a is a flat plate and can be made of materials such as sapphire, SiC, Si or GaN and so on. In this embodiment, the temporary substrate 12a is made of sapphire.

The N-type semiconductor layer 16a, the active layer 15 and P-type semiconductor layer 14 are sequentially formed on the temporary substrate 12a by metal-organic chemical vapor deposition (MOCVD), molecular beam epitaxy (MBE) or hydride vapor phase epitaxy (HVPE). In this embodiment, the N-type semiconductor layer 16a is an N-type GaN layer, the active layer 15 is a multiple quantum well GaN/InGaN layer, and the P-type semiconductor layer 14 is a P-type GaN layer.

The reflective layer 13 is formed on the P-type semiconductor layer 14. In this embodiment, the reflective layer 13 is formed by plasma enhanced chemical vapor deposition method.

Thereafter, a conductive substrate 12 is formed on the reflective layer 13 by electroplating or die bonding.

The semi-finished product of the light source 10 after the above process is turned upside down with the temporary substrate 12a being located at a top thereof. Then the temporary substrate 12a is removed to expose a surface of the N-type semiconductor layer 16a which is away from the active layer 15.

The exposed surface of the N-type semiconductor layer 16a is a light outputting surface 18a of the semi-finished product of the light source 10.

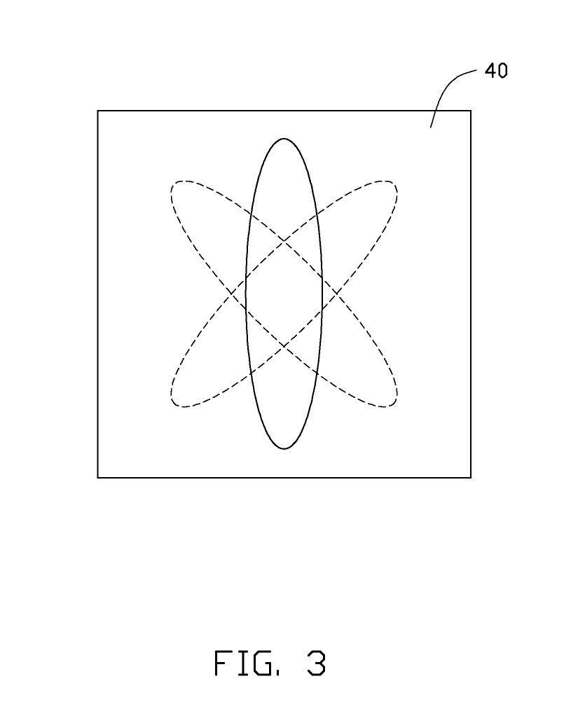

Referring to FIG. 3, a mask 40 having an elliptical opening in a center thereof is provided to cover the light outputting surface 18a. The mask 40 is square and has an area and shape meeting the area and shape of the light outputting surface 18a whereby the mask 40 can totally cover the light outputting surface 18a. A laser source (not shown), for example, a pulse laser source radiates a laser beam to the light outputting surface 18a through the opening of the mask 40 to etch a portion of the light outputting surface 18a which is not covered by the mask 40. During the laser etching, the semi-finished product of the light source 10 is rotated, whereby a circular concavity can be formed in the light outputting surface 18a. By the laser etching, a part of the N-type semiconductor layer 16a is removed and a concave surface 19 which is round is formed at a center of the light outputting surface 18a. Accordingly, the light outputting surface 18 having the concave surface 19 is formed. The pads 17 are then attached to opposite sides of the flat part of the light outputting surface 18, which is located adjacent to a periphery of the concave surface 19 of the light outputting surface 18. In this embodiment, the laser is a KrF excimer laser with small energy applied to precisely process the light outputting surface 18a. Since the concave surface 19 is formed by laser etching, the concave surface 19 can be easily formed; other etching method, such as chemical etching can form a cavity with a vertical edge or a bevel edge, other than an arced edge as disclosed by the present disclosure.

It is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A light emitting diode (LED) die, comprising:
a substrate;
multiple semiconductor layers formed on the substrate, wherein a top surface of one of the multiple semiconductor layers away from the substrate forms a light outputting surface and wherein a concave surface which is round is formed in a center of the light outputting surface, the concave surface being an aspheric and arc-shaped surface and having an arc-shaped edge connecting with a flat part of the light outputting surface which surrounds the concave surface.

2. The LED die of claim 1, wherein the substrate is an electrically conductive substrate, and the multiple semiconductor layers comprise a P-type semiconductor layer on the electrically conductive substrate, an active layer on the P-type semiconductor layer, an N-type semiconductor layer on the active layer and electrically conductive pads, a top surface of the N-type semiconductor layer forming the light outputting surface and the electrically conductive pads being located on the flat part of the light outputting surface, the concave surface being formed at a center of the top surface of the N-type semiconductor layer.

3. The LED die of claim 2, wherein the pads are disposed at a periphery of the light outputting surface and located above of the concave surface.

4. The light emitting diode package of claim 2 further comprising a reflective layer, wherein the reflective layer is located between the conductive substrate and the P-type semiconductor layer.

5. An LED automobile lamp, comprising:
a lens;
a light source, the light source being an LED chip and spaced from the lens, the light source comprising a light outputting surface, an concave surface being round in shape and being formed in a center of the light outputting surface, the concave surface being an aspheric and arc-shaped surface and having an arc-shaped edge connecting with a flat part of the light outputting surface which surrounds the concave surface, the light outputting surface directly facing to the lens.

6. The LED automobile lamp of claim 5 further comprising a shading portion disposed between the light source and the lens, wherein the shading portion provides a cut-off line to regulate lights generated by the LED die to a preset luminance shape.

7. The LED automobile lamp of claim 5, wherein the LED die comprises a conductive substrate, a P-type semiconductor layer, an active layer, an N-type semiconductor layer and conductive pads arranged sequentially along a height direction on the conductive substrate of the LED die, a surface of the N-type semiconductor layer being exposed to form the light outputting surface and the concave surface being formed at a center of the exposed surface of the N-type semiconductor layer.

8. The LED automobile lamp of claim 7, wherein the conductive pads are disposed at a periphery of the light outputting surface and located above of the concave surface.

9. The LED automobile lamp of claim 7, wherein the LED die further comprises a reflective layer, wherein the reflective layer is located between the conductive substrate and the P-type semiconductor layer.

10. A method for manufacturing an LED die for use in an automobile headlamp comprising steps:
providing a substrate and multiple semiconductor layers on the substrate wherein a top surface of the multiple semiconductor layers away from the substrate functions as a light outputting surface; and
etching a center of the light outputting surface to form a concave surface by laser etching, the concave surface being a aspheric, arc-shaped surface.

11. The method for manufacturing an LED die of claim 10, wherein before the step of providing a substrate, the method comprises:
providing a temporary substrate, forming the multiple semiconductor layers on the temporary substrate, wherein the multiple semiconductor layers comprise an N-type semiconductor layer on the temporary substrate, an active layer on the N-type semiconductor layer and a P-type semiconductor layer on the active layer;
wherein the step of providing a substrate comprises:
forming a conductive substrate on the P-type semiconductor layer; and
removing the temporary substrate to expose a surface of the N-type semiconductor layer, the exposed surface of the N-type semiconductor layer functioning as the light outputting surface and the conductive substrate functioning as the substrate;
wherein before the step of etching a center of the light outputting surface, the method further comprises providing a laser mask with an elliptical opening to cover the light outputting surface; and
wherein the etching of a center of the light outputting surface is performed by having a laser beam radiating through the elliptical opening to etch the center of the light outputting surface.

12. The method for manufacturing an LED die of claim 11, wherein during the step of etching a center of the light output surface, the LED die is rotated.

13. The method for manufacturing an LED die of claim 11, further comprising a step of forming a reflective layer between the P-type semiconductor layer and the conductive substrate, wherein the reflective layer is formed by plasma enhanced chemical vapor deposition method.

14. The method for manufacturing an LED die of claim 11, wherein the laser beam is generated by using an KrF excimer laser.
